(19) United States
(12) Patent Application Publication
(10) Pub. No.: US 2008/0224138 A1
(43) Pub. Date: Sep. 18, 2008

(54) Image Sensor and Method of Manufacturing the Same

(76) Inventor: MIN HYUNG LEE, Cheongjoo-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,831

(22) Filed: Aug. 21, 2007

(30) Foreign Application Priority Data
Mar. 14, 2007 (KR) 10-2007-0024918

(51) Int. Cl. H01L 31/0376; H01L 31/18

(52) U.S. Cl. 257/53; 438/96; 257/E31.048

(57) ABSTRACT

Disclosed is an image sensor, which includes a substrate having a transistor circuit and lower interconnections. First interconnections are formed separated from each other on the substrate and electrically connected to the CMOS circuitry through the lower interconnections. Planarized insulating layers are formed between the first interconnections to isolate unit pixels. An intrinsic layer is formed on the substrate including the insulating layers, and a second conductive layer is formed on the intrinsic layer. The first interconnections, the intrinsic layer and the second conductive layer provide a photodiode structure for the image sensor.

### CROSS-REFERENCE TO RELATED APPLICATION

The present application claims the benefit under 35 U.S.C. §119 of Korean Patent Application No. 10-2007-0024918, filed Mar. 14, 2007, which is hereby incorporated by reference in its entirety.

### BACKGROUND

In general, image sensors are semiconductor devices for converting an optical image into an electrical signal, and are roughly classified as a charge coupled device (CCD) image sensor or a complementary metal oxide semiconductor (CMOS) image sensor (CIS).

The CIS includes a photodiode and a MOS transistor in each unit pixel. Thus, the CIS sequentially detects electrical signals of the respective unit pixels in a switching mode, thereby realizing an image.

The related CIS includes a photodiode region that receives an optical signal to convert it into an electrical signal, and a transistor region that processes the electrical signal.

This related CIS has a structure in which the photodiode and the transistor are horizontally disposed.

The related CIS overcomes drawbacks of the CCD image sensor, but still has problems to be solved.

Specifically, according to the related CIS having the horizontal structure, the photodiode and the transistor are formed horizontally adjacent to each other on the substrate. Thus, the CIS requires an additional region for the photodiode on the substrate. Thereby, the CIS decreases a region corresponding to a fill factor, and restricts a possibility to increase resolution thereof.

Further, according to the related CIS having the horizontal structure, it is very difficult to optimize a process of simultaneously forming the photodiode and the transistor. In other words, the process of forming the transistor requires shallow junction for low sheet resistance, but such shallow junction may not be suitable for the process of forming the photodiode.

In addition, according to the related CIS having the horizontal structure, on-chip functions are additionally provided. Thus, a size of the unit pixel should be increased in order to maintain sensitivity of the CIS, or an area for the photodiode should be decreased in order to maintain a pixel size. However, when the pixel size is increased, the resolution of the CIS is decreased. Further, when the area for the photodiode is decreased, the sensitivity of the CIS is decreased.

### BRIEF SUMMARY

Accordingly, embodiments of the present invention are directed to an image sensor and a method of manufacturing the same, capable of providing a vertical integration of transistor circuitry and photodiodes.

An image sensor and a method of manufacturing the same according to embodiments of the present invention are capable of improving resolution together with sensitivity.

According to embodiments of the present invention, an image sensor and a method of manufacturing the same are provided that are capable of employing a vertical photodiode and inhibiting defects from occurring with respect to the photodiode.

According to an embodiment, an image sensor includes a substrate having a transistor circuit including lower interconnections, first interconnections formed above the transistor circuit and electrically connected to corresponding lower interconnections, insulating layers that are planarized between the first interconnections, an intrinsic layer that is formed on the substrate including the insulating layers, and a second conductive layer that is formed on the intrinsic layer.

Further, according to an embodiment, a method of manufacturing an image sensor comprises forming a transistor circuit including lower interconnections on a substrate; forming first interconnections electrically connected to corresponding lower interconnections of the lower interconnections separated from each other on the substrate; forming insulating layers on the first interconnections; planarizing the insulating layers; forming an intrinsic layer on the planarized insulating layers; and forming a second conductive layer on the intrinsic layer.

### BRIEF DESCRIPTION OF THE DRAWINGS

FIGS. 1 through 5 are cross-sectional views illustrating a method of manufacturing an image sensor according to an embodiment of the present invention.

### DETAILED DESCRIPTION

Hereinafter, an image sensor and method of manufacturing the same according to embodiments of the present invention will be described with reference to the accompanying drawings.

In the description, it will be understood that, when a layer is referred to as being “on/under” another layer or substrate, it can be directly on/under the other layer or substrate, or one or more intervening layers may also be present.

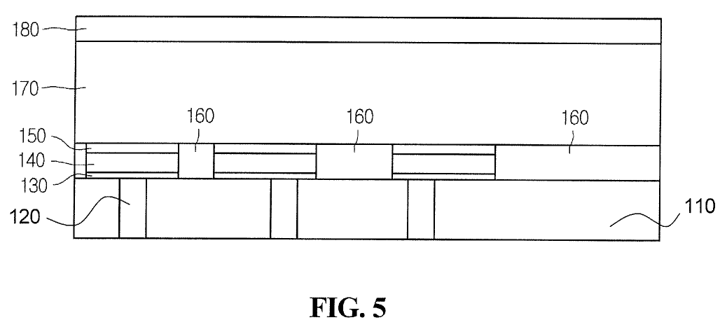

FIG. 5 is a cross-sectional view illustrating an image sensor according to an embodiment.

The image sensor includes a substrate having complementary metal oxide semiconductor (CMOS) circuitry (not shown). Lower interconnections 120 are formed to connect photodiodes to the CMOS circuitry. The photodiode portions of the image sensor can include first interconnections 140, insulating layers 160 planarized between the first interconnections 140, an intrinsic layer 170 formed on the first interconnections 140 and the insulating layers 160, and a second conductive layer 180 formed on the intrinsic layer 170. First conductive layers 150 can be additionally formed on the first interconnections 140.

It should be noted that the photodiodes, which are formed on the upper surface of the interlayer dielectric layer 110 and receive an incident light from the outside to convert and maintain the light into an electrical form, are illustrated in FIG. 5 as PIN diodes.

The PIN diode is formed in a structure where a n-type amorphous silicon, an intrinsic amorphous silicon, and a p-type amorphous silicon are bonded. The performance of the photodiode is decided depending on the efficiency of receiving light from the outside and converting it into an electrical form, and total charge capacitance. The related art photodiode formed in a substrate generates and stores charge at a depletion region generated in a hetero-junction such as P-N, N-P, N-P-N, and P-N-P. However, the PIN diode is advantageous in generating and storing the charge, since the entire intrinsic amorphous silicon layer formed between the p-type silicon layer and the n-type silicon layer becomes the depletion region.

When a PIN diode is used as the photodiode, the structure of the PIN diode can be the structure of a P-I-N or a N-I-P. In particular, in the described embodiments, the PIN diode having the P-I-N structure is used by way of an example, and the n-type amorphous silicon is referred to as the first conductive layer 150, the intrinsic amorphous silicon is referred to as the intrinsic layer 170, and the p-type amorphous silicon is referred to as the second conductive layer 180. In other embodiments, a PIM diode can be used. A PIM diode differs from a PIN diode by not utilizing an n-type conductive layer (“N”). Rather, a lower electrode of a metal layer is used (“M”). The metal layer can be any metal that is capable of being silicided at a low temperature, such as not more than 400° C. and preferably not more than 300° C. For example, the metal layer can be formed of Cr, Mo, or W. In embodiments adopting the PIM structure, the first interconnections 140 can be used as the “M” layer of the PIM diode.

In the image sensor according embodiments of the present invention, the transistor circuitry and the photodiodes are vertically integrated. Therefore, the image sensor enables a fill factor to approach 100%, and can provide sensitivity higher than that of the related image sensor for the same pixel size.

Further, in comparison with the related image sensor, the image sensor according to embodiments of the present invention can further reduce process cost for the same resolution, and realize more complicated transistor circuitry in each unit pixel without reduction of the sensitivity.

Moreover, additional on-chip circuitry can be integrated to increase performance of the image sensor, and furthermore obtain miniaturization of the device as well as reduction of production cost.

In addition, according to the above described embodiment, the intrinsic layer 170 is formed on the planarized insulating layers 160, and thereby avoids an additional planarizing process. Accordingly, the image sensor can inhibit defects from occurring in the photodiode.

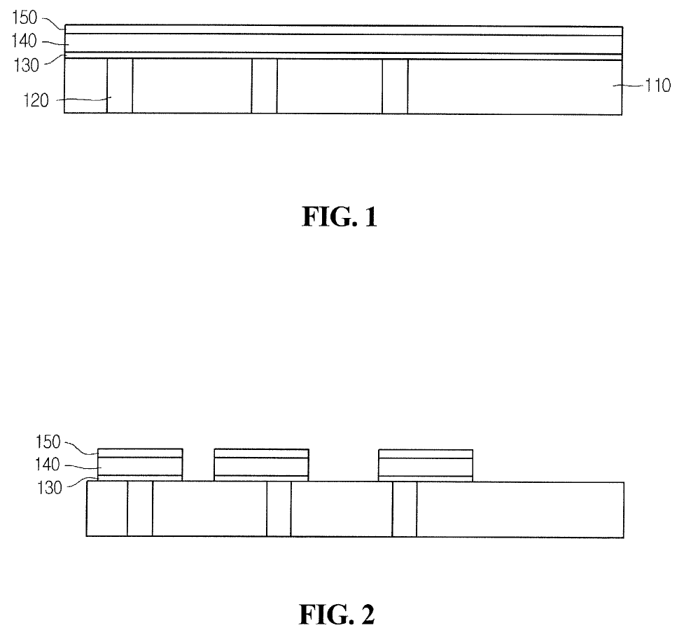

Referring to FIG. 1, CMOS circuitry (not shown) including lower interconnections 120 formed in an interlayer dielectric layer (ILD) 110 can be formed on a substrate (not shown).

In one embodiment, barrier metal 130 can be formed on the ILD 110. The barrier metal 130 can be formed of, for example, Ta, Tan, Ti, Tin, TiSiN, or TaSiN. In other embodiments, the barrier metal 130 may be omitted.

Then, a material layer for first interconnections 140 can be formed on the barrier metal 130. The material layer for first interconnections 140 can be formed of any one of various conductive materials including metal, alloy, and silicide. For example, the material layer for the first interconnections 140 can be formed of aluminum, copper, chrome, or cobalt.

Subsequently, a first conductive layer 150 can be formed on the first interconnection layer 140. In some embodiments, the first conductive layer 150 can be omitted. The first conductive layer 150 can serve as the “N” layer of a PIN diode. In other words, the first conductive layer 150 can include, but is not limited to, an N-type conductive type conductive layer.

The first conductive layer 150 can be formed of, but not limited to, n-doped amorphous silicon. For example, the first conductive layer 150 can be formed of a material, which adds Ge, C, N₂, or O₂ to amorphous silicon, such as a-Si:H, a-SiGe:H, a-SiC, a-SiN:H, a-SiO:H, or the like.

The first conductive layer 150 can be formed by a chemical vapor deposition (CVD) such as plasma enhanced CVD (PECVD). For example, the first conductive layer 150 can be formed of amorphous silicon through PECVD by using a mixture gas obtained by mixing PH₃ or P₂H₅ with silane (SiH₄) gas.

In an embodiment, the first conductive layer 150 can be formed at a thickness from about 400 Å to about 1000 Å.

Next, referring to FIG. 2, a plurality of first interconnections 140 can be formed.

Specifically, a first mask pattern (not shown) can be formed on the first conductive layer 150. Then, the first conductive layer 150, the first interconnection layer 140 and the barrier metal 130 can be etched using the first mask pattern (not shown) as an etch mask, thereby forming the first conductive layers 150, the first interconnections 140 and the barrier metals 130.

This process of separating the first interconnections 140 (and the first conductive layer 150 and barrier film 130) into patterns can inhibit cross talk between the unit pixels.

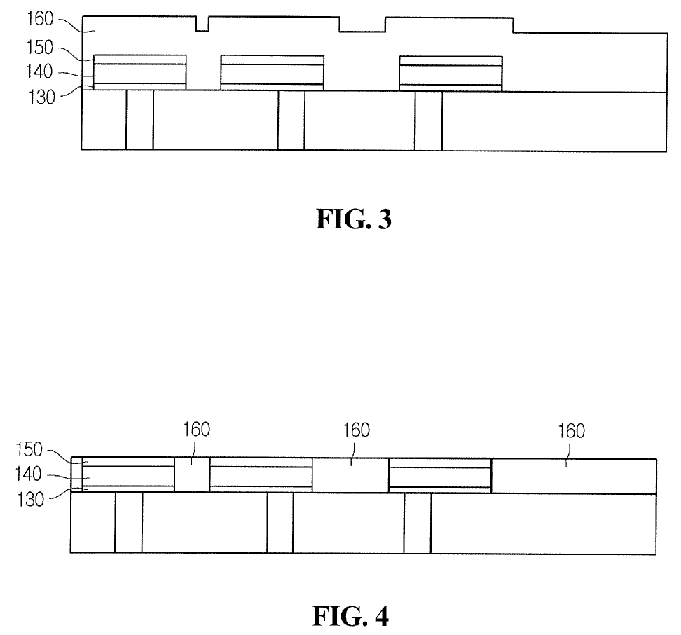

Then, referring to FIG. 3, an insulating layer 160 can be formed on the substrate including the separated first conductive layers 150. The insulating layer 160 positively enables the insulation between the unit pixels. For example, the insulating layer 160 can be formed of an oxide, nitride or low-k dielectric.

Next, referring to FIG. 4, a process of planarizing the insulating layer 160 can be carried out.

According to such an embodiment, the insulating layer 160 is planarized to provide a planarized surface for an intrinsic layer, and thus the intrinsic layer 170 formed in a subsequent process does not need to be planarized. Therefore, defects generated within the photodiode are minimized, and thereby dark current caused by these defects can be inhibited from occurring.

The method of planarizing the insulating layers 160 can be a chemical mechanical polishing (CMP) process.

After performing the planarization process, a process of cleaning the substrate including the planarized insulating layers 160 can be performed.

Next, referring to FIG. 5, an intrinsic layer 170 can be formed on the substrate including the planarized insulating layers 160. The intrinsic layer 170 can serve as an “I” layer of a PIN diode.

The intrinsic layer 170 can be formed of amorphous silicon. The intrinsic layer 170 can be formed by CVD, such as PECVD. For example, the intrinsic layer 170 can be formed of amorphous silicon using silane (SiH₄) gas by PECVD.

The intrinsic layer 170 can be formed at a thickness of 4,000 Å or more. This is because light having a long wavelength of 4,000 Å or more cannot be absorbed by the intrinsic layer 170 when the thickness of the intrinsic layer 170 is less than 4,000 Å. In an embodiment, the intrinsic layer 170 can be formed at a thickness from about 4,000 Å to about 12,000 Å.

Thereafter, a second conductive layer 180 can be formed on the intrinsic layer 170. The second conductive layer 180 can serve as a “P” layer of a PIN diode. In other words, the second conductive layer 180 can include, but is not limited to, a P-type conductive type conductive layer.

The second conductive layer 180 can be formed of, for example, p-doped amorphous silicon.

The second conductive layer 180 can be formed by CVD, such as PECVD. For example, the second conductive layer 180 can be formed of amorphous silicon through PECVD using a mixture of gas obtained by mixing boron with silane (SiH₄) gas.

The second conductive layer 180 can be formed at a thickness of 1,000 Å or less. This is because light having a wavelength of 1,000 Å or more is absorbed by the second conductive layer 180 when the second conductive layer 180 has a thickness of 1,000 Å or more, and thus photo-electrons generated from the second conductive layer 180 may not be efficiently generated. In an embodiment, the second conductive layer 180 can be formed at a thickness from about 100 Å to about 1,000 Å, so that it can serve as an optimal P-type conductive type conductive layer.

In further embodiments, an upper electrode (not shown) can be formed on the upper surface of the substrate on which the photodiode is formed. The upper electrode can be formed of a transparent electrode having good light transmission and conductivity. For example, the upper electrode can be formed of ITO, CTO, or ZnO₂. A color filter layer and a microlense can additionally be provided.

In the method of manufacturing an image sensor, the transistor circuitry and the photodiode are vertically integrated, so that the method enables the fill factor to approach about 100%, and furthermore can provide sensitivity higher than that of the related image sensor having the same pixel size.

Further, in comparison with the related method, the method according to an embodiment can further reduce process cost for the same resolution, and realize more complicated transistor circuitry in each unit pixel without reduction of the sensitivity.

Moreover, additional on-chip circuitry can be integrated to increase performance of the image sensor, and furthermore obtain miniaturization of the device as well as reduction of production cost.

In addition, the intrinsic layer can be formed on planarized insulating layers, thereby avoiding requiring additional planarizing work. Accordingly, the method can inhibit defects from occurring in the photodiode.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a substrate having a transistor circuit formed therein;
first interconnections separated from each other on the substrate and electrically connected to the transistor circuit through lower interconnections;
insulating layers planarized between the first interconnections;
an intrinsic layer formed on the substrate including the insulating layers; and
a second conductive layer formed on the intrinsic layer.

2. The image sensor according to claim 1, wherein the first interconnections comprise a metal layer capable of being silicided at a low temperature.

3. The image sensor according to claim 1, further comprising a barrier metal formed between the first interconnections and the lower interconnections.

4. The image sensor according to claim 1, further comprising first conductive layers formed on the first interconnections below the intrinsic layer, wherein a top surface of the first conductive layers has the same height as a top surface of the insulating layers.

5. The image sensor according to claim 4, wherein the first conductive layers comprise doped amorphous silicon.

6. A method of manufacturing an image sensor, comprising:
forming a transistor circuit and lower interconnections on a substrate;
forming first interconnections separated from each other on the substrate and electrically connected to the transistor circuit through the lower interconnections;
forming an insulating layer on the substrate;
planarizing the insulating layer to form planarized insulating layers between the first interconnections;
forming an intrinsic layer on the planarized insulating layers; and
forming a second conductive layer on the intrinsic layer.

7. The method according to claim 6, wherein forming first interconnections comprises:
depositing a metal layer on the substrate; and
etching the metal layer using an etch mask covering regions of the metal layer above the lower interconnections.

8. The method according to claim 7, wherein the metal layer comprises a metal capable of being silicided at a low temperature.

9. The method according to claim 6, wherein planarizing the insulating layer comprises performing chemical mechanical polishing (CMP).

10. The method according to claim 6, further comprising forming barrier metal on the substrate before forming the first interconnections, wherein the barrier metal is formed to be below each separated first interconnection.

11. The method according to claim 10, further comprising forming first conductive layers on the first interconnections before forming the insulating layer,
wherein forming the barrier metal, forming the first interconnections, and forming the first conductive layers comprises:
depositing a barrier metal on the substrate including the lower interconnections;
depositing a metal layer for the first interconnections on the barrier metal;
forming a first conductive layer on the metal layer;
forming an etch mask on the first conductive layer covering regions of the first conductive layer above the lower interconnections; and
etching the first conductive layer, the metal layer, and the barrier metal using the etch mask.

12. The method according to claim 11, wherein forming the first conductive layer comprises:
depositing a doped amorphous silicon layer on the substrate.

13. The method according to claim 6, further comprising forming first conductive layers on the first interconnections before forming the insulating layer,
wherein forming the first interconnections and forming the first conductive layers comprises:
depositing a metal layer on the substrate;
forming a first conductive layer on the metal layer;
forming an etch mask on the first conductive layer covering regions of the first conductive layer above the lower interconnections; and
etching the first conductive layer and the metal layer using the etch mask.

14. The method according to claim 13, wherein forming the first conductive layer comprises:
depositing a doped amorphous silicon layer on the substrate.

15. The method according to claim 6, further comprising cleaning the substrate after planarizing the insulating layer.
